(19) United States
(12) Patent Application Publication
(10) Pub. No.: US 2011/0278269 A1
(43) Pub. Date: Nov. 17, 2011

(54) METHOD AND SYSTEM FOR ELECTRICAL CIRCUIT REPAIR

(75) Inventors: Uri Gold, Rishon Lezion (IL); Zvi Kotler, Tel Aviv (IL)

(73) Assignee: Orbotech Ltd., Yavne (IL)

(21) Appl. No.: 13/146,200

(22) PCT Filed: Feb. 7, 2010
(86) PCT No.: PCT/IL10/00106

§ 371 Date: Jul. 26, 2011

(30) Foreign Application Priority Data
Mar. 2, 2009 (IL) 197349

(51) Int. Cl. B23K 26/38

(52) U.S. Cl. 219/121.69; 219/121.68

(57) ABSTRACT

A system and method of repairing electrical circuits including employing a laser and at least one laser beam delivery pathway for laser pre-treatment of at least one conductor repair area of a conductor formed on a circuit substrate and employing the laser and at least part of the at least one laser beam delivery pathway for application of at least one laser beam to a donor substrate in a manner which causes at least one portion of the donor substrate to be detached therefrom and to be transferred to at least one predetermined conductor location.

### FIELD OF THE INVENTION

The present invention relates to electrical circuit repair generally.

### CROSS-REFERENCE TO RELATED APPLICATION

This application claims benefit of Israeli Patent Application No. 197349 entitled “A Method and System for Electrical Circuit Repair”, filed 2 Mar. 2009; the above noted prior application is incorporated herein by reference.

### BACKGROUND OF THE INVENTION

The following publications are believed to represent the current state of the art:

U.S. Pat. Nos. 4,752,455; 4,970,196; 4,987,006; 5,173,441 and 5,292,559;

“Metal deposition from a supported metal film”, Bohandy, B. F. Kim and F. J. Adrian, J. Appl. Phys. 60 (1986) 1538; and

“A study of the mechanism of metal deposition by the laser-induced forward transfer process”, F. J. Adrian, J. Bohandy, B. F. Kim, and A. N. Jette, Journal of Vacuum Science and Technology B 5, 1490 (1989), pp. 1490-1494.

### SUMMARY OF THE INVENTION

The present invention seeks to provide an improved system and method for electrical circuit repair.

There is thus provided in accordance with a preferred embodiment of the present invention a method of repairing electrical circuits including employing a laser and at least one laser beam delivery pathway for laser pre-treatment of at least one conductor repair area of a conductor formed on a circuit substrate and employing the laser and at least part of the at least one laser beam delivery pathway for application of at least one laser beam to a donor substrate in a manner which causes at least one portion of the donor substrate to be detached therefrom and to be transferred to at least one predetermined conductor location.

In accordance with a preferred embodiment of the present invention the pre-treatment includes laser ablation. Preferably, the laser is operated at different power levels during the laser pre-treatment and the application to the donor substrate.

In accordance with a preferred embodiment of the present invention the pre-treatment includes pre-treatment of a substrate repair area and pre-treatment of a conductor repair area. Additionally, the laser ablation produces surface roughening of the substrate repair area and the conductor repair area. Additionally, the pre-treatment of the substrate repair area and the pre-treatment of the conductor repair area include different extents of surface roughening.

Preferably, the at least one conductor repair area is selected by automated optical inspection.

In accordance with a preferred embodiment of the present invention the method of repairing electrical circuits also includes employing the laser and the at least one laser beam delivery pathway for laser ablation of excess conductor material. Additionally, the excess conductor material is formed by material detached from the donor substrate. Additionally or alternatively, the laser ablation of excess conductor material is performed subsequent to the application of at least one laser beam to a donor substrate, which is in turn performed subsequent to the laser pre-treatment.

There is also provided in accordance with another preferred embodiment of the present invention a method of repairing electrical circuits including employing a laser and at least one laser beam delivery pathway for laser ablation of excess conductor material in at least one conductor repair area of a conductor formed on a circuit substrate and employing the laser and at least part of the at least one laser beam delivery pathway for application of at least one laser beam to a donor substrate in a manner which causes at least one portion of the donor substrate to be detached therefrom and to be transferred to at least one predetermined conductor location.

In accordance with a preferred embodiment of the present invention the laser ablation of excess conductor material effects repair of short circuits. Preferably, the laser is operated at different power levels during the laser ablation and the application to the donor substrate.

In accordance with a preferred embodiment of the present invention the method of repairing electrical circuits also includes surface roughening of the at least one conductor repair area. Preferably, the at least one conductor repair area is selected by automated optical inspection.

There is further provided in accordance with yet another preferred embodiment of the present invention a method of repairing electrical circuits including pre-treatment of at least one circuit substrate repair area of a circuit substrate and of at least one conductor repair area of a conductor formed on the circuit substrate and lying adjacent the at least one circuit substrate repair area and applying at least one laser beam to a donor substrate in a manner which causes at least one portion of the donor substrate to be detached therefrom and to be transferred to at least one predetermined circuit substrate location in the at least one circuit substrate repair area and to at least one predetermined conductor location in the at least one conductor repair area, thereby to at least partially overlap a portion of the conductor at the at least one conductor repair area and to form at least an extension of the conductor in the at least one circuit substrate repair area.

In accordance with a preferred embodiment of the present invention the pre-treatment includes laser ablation. Additionally, the laser ablation produces surface roughening.

Preferably, the pre-treatment and the applying are carried out by the same laser. Additionally, the pre-treatment and the applying are carried out by the same laser at different power levels.

In accordance with a preferred embodiment of the present invention the pre-treatment of the substrate repair area and of the conductor repair area are carried out by the same laser at different power levels. Additionally, the pre-treatment of the substrate repair area and of the conductor repair area include different extents of surface roughening.

Preferably, the at least one predetermined substrate location in the at least one substrate repair area and the at least one predetermined conductor location in the at least one conductor repair area are selected by automated optical inspection.

There is even further provided in accordance with still another preferred embodiment of the present invention a system for repairing electrical circuits including a laser and a laser beam delivery pathway, laser pre-treatment functionality utilizing the laser and at least part of the laser beam delivery pathway for laser pre-treatment of at least one conductor repair area of a conductor formed on a circuit substrate and conductor deposition functionality utilizing the laser and at least part of the laser beam delivery pathway for application of at least one laser beam to a donor substrate in a manner which causes at least one portion of the donor substrate to be detached therefrom and to be transferred to at least one predetermined conductor location.

There is yet further provided in accordance with another preferred embodiment of the present invention a system for repairing electrical circuits including a laser and a laser beam delivery pathway, excess conductor ablation functionality employing the laser and at least part of the laser beam delivery pathway for laser ablation of excess conductor material in at least one conductor repair area of a conductor formed on a circuit substrate and conductor deposition functionality employing the laser and at least part of the laser beam delivery pathway for application of at least one laser beam to a donor substrate in a manner which causes at least one portion of the donor substrate to be detached therefrom and to be transferred to at least one predetermined conductor location.

Preferably, the laser ablation of excess conductor material effects repair of short circuits.

There is still further provided in accordance with yet another preferred embodiment of the present invention a system for repairing electrical circuits including a laser and a laser beam delivery pathway, pre-treatment functionality employing the laser and at least part of the laser beam delivery pathway for treatment of at least one circuit substrate repair area of a circuit substrate and of at least one conductor repair area of a conductor formed on the circuit substrate and lying adjacent the at least one circuit substrate repair area and conductor deposition functionality employing the laser and at least part of the laser beam delivery pathway for application of at least one laser beam to a donor substrate in a manner which causes at least one portion of the donor substrate to be detached therefrom and to be transferred to at least one predetermined circuit substrate location in the at least one circuit substrate repair area and to at least one predetermined conductor location in the at least one conductor repair area, thereby to at least partially overlap a portion of the conductor at the at least one conductor repair area and to form at least an extension of the conductor in the at least one circuit substrate repair area.

### BRIEF DESCRIPTION OF THE DRAWINGS

The present invention will be understood and appreciated more fully from the following detailed description, taken in conjunction with the drawings in which:

FIG. 1 is a simplified illustration of a system for repairing electrical circuits, constructed and operative in accordance with a preferred embodiment of the present invention;

FIG. 2 is a simplified illustration of an embodiment of the optical subsystem of the system of FIG. 1;

FIGS. 3A-3H are simplified sectional illustrations showing the operation of the system of FIG. 1.

FIG. 4 is a simplified illustration of additional functionality of the system of FIG. 1;

FIGS. 5A-5C are simplified sectional illustrations showing the operation of the functionality of FIG. 4.

### DETAILED DESCRIPTION OF EMBODIMENTS

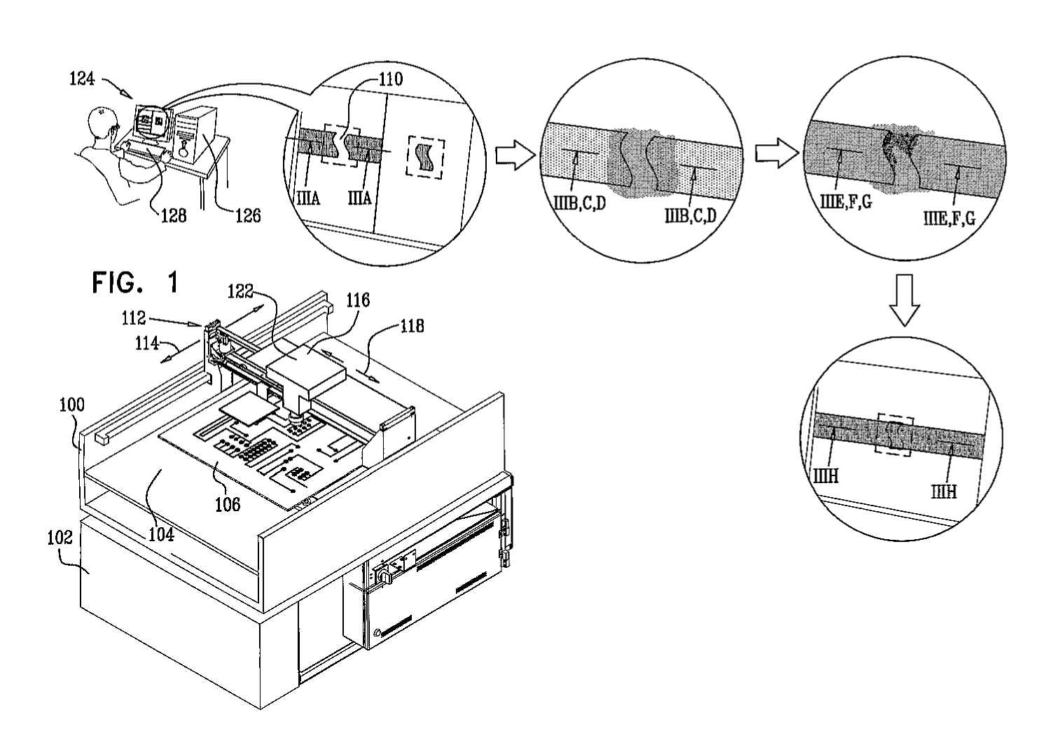

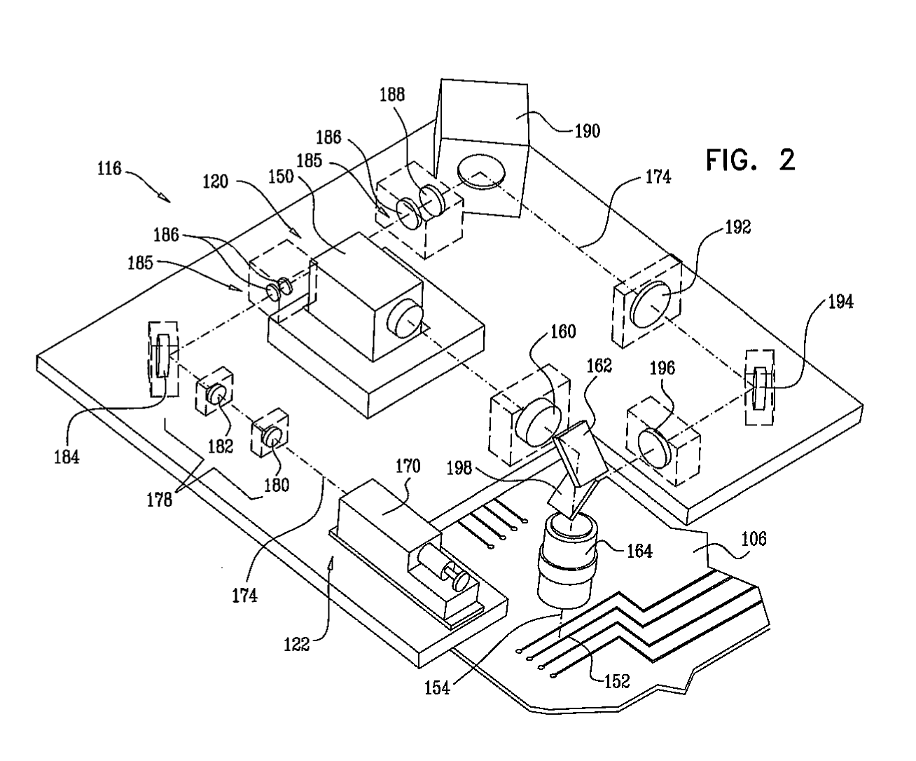

Reference is now made to FIG. 1, which is a simplified illustration of a system for repairing electrical circuits, constructed and operative in accordance with a preferred embodiment of the present invention, and to FIG. 2, which is a simplified illustration of an embodiment of the optical subsystem of the system of FIG. 1.

As seen in FIG. 1, the system preferably comprises a chassis 100 which is preferably mounted on a conventional optical table 102. The chassis 100 defines an electrical circuit inspection location 104 onto which an electrical circuit, such as a printed circuit board (PCB) 106, to be inspected may be placed. The PCB 106 typically has one or more of various types of defects, such as excess conductor defects and missing conductor defects, for example cut 110.

A bridge 112 is arranged for linear motion relative to inspection location 104 along a first inspection axis 114 defined with respect to chassis 100. An optical head assembly 116 is arranged for linear motion relative to bridge 112 along a second inspection axis 118, perpendicular to first inspection axis 114.

In accordance with a preferred embodiment of the present invention, as seen in detail in FIG. 2, the optical head assembly 116 preferably includes an inspection subassembly 120 and a repair subassembly 122. It is a particular feature of the present invention that the inspection subassembly 120 and the repair subassembly 122 share at least some optical components.

The system preferably also includes a control assembly 124, preferably including a computer 126 having a user interface 128 and including software modules operative to operate the inspection subassembly 120 and repair subassembly 122. Control assembly 124 preferably receives a defect location input from an automatic optical inspection system, not shown, such as a Discovery 8000 system, commercially available from Orbotech Ltd. of Yavne, Israel.

As seen in FIG. 2, optical head assembly 116 includes inspection subassembly 120 and repair subassembly 122. Inspection subassembly 120 is a parafocal imaging system, which includes a camera 150, such as a Basler CMOS camera available from Basler, Inc. of Exton Pa. imaging location 152 on PCB 106 along an optical axis 154. Camera 150 views location 152 through a focusing object lens 160, having a typical focal length of 100-150 mm, a partial reflective mirror 162 and an objective lens module 164, such as a 5×/0.14 objective lens module, commercially available from Mitutoyo Ltd. of Japan.

In accordance with an embodiment of the invention, inspection subassembly 120 and repair subassembly 122 are arranged to at least partly share the same optical path along optical axis 154. The repair subassembly 122 includes a pulsed laser source 170, such as a passive Q-switch micro laser available from Teem Photonoics of Grenoble, France, operative to generate a pulsed laser beam 174. A suitable micro laser may be selected, for example, from laser heads operative to output beams at a wavelength of 532 nm or at 1064 nm, depending on the application. Pulsed beam 174 is passed through collimating optics 178, which may include two lenses 180 and 182, having focal lengths of 80 mm and −150 mm respectively, operative to collimate the laser beam 174 to a preferred spot size of 0.5-3.0 mm. Laser beam 174 is then reflected by mirror 184 and is then adjusted to a specific diameter by a beam expender 185, including multiple lenses 186 placed and adjusted for the required size of collimated output beam. Lenses 186 may include lenses such as a 28 mm plano-convex lens, a −10 mm biconcave lens and a 129 mm plano-convex lens, respectively. Laser beam 174 is then directed by a lens 188 to impinge on a two-axis fast steering mirror (FSM) 190, commercially available from Newport Corporation, and then passes through a lens 192, such as a 108 mm meniscus lens, a mirror 194 and a lens 196, such as plano convex 338 mm lens. Lenses 188, 192 and 196 maintain the position of the beam on the FSM 190, which is located after lens 188, and the input aperture of objective lens module 164. Beam 174 then impinges on beam splitter 198, which directs beam 174 through objective lens module 164 along axis 154. In accordance with a preferred embodiment of the invention, the lenses and optical components are arranged as shown and are suitably coated for operation in conjunction with the selected wavelength of laser beam 174.

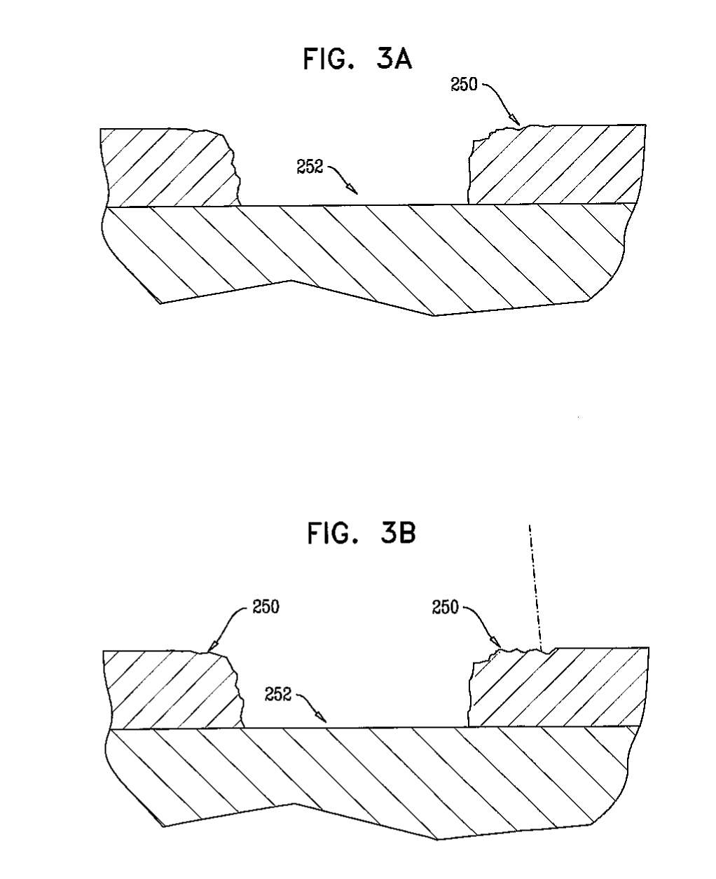

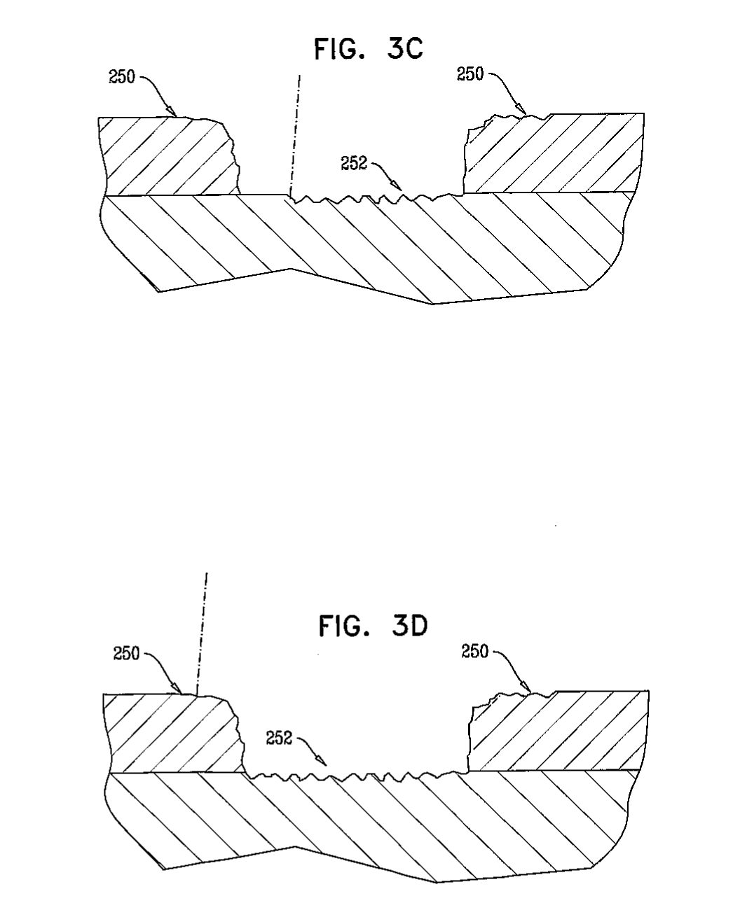

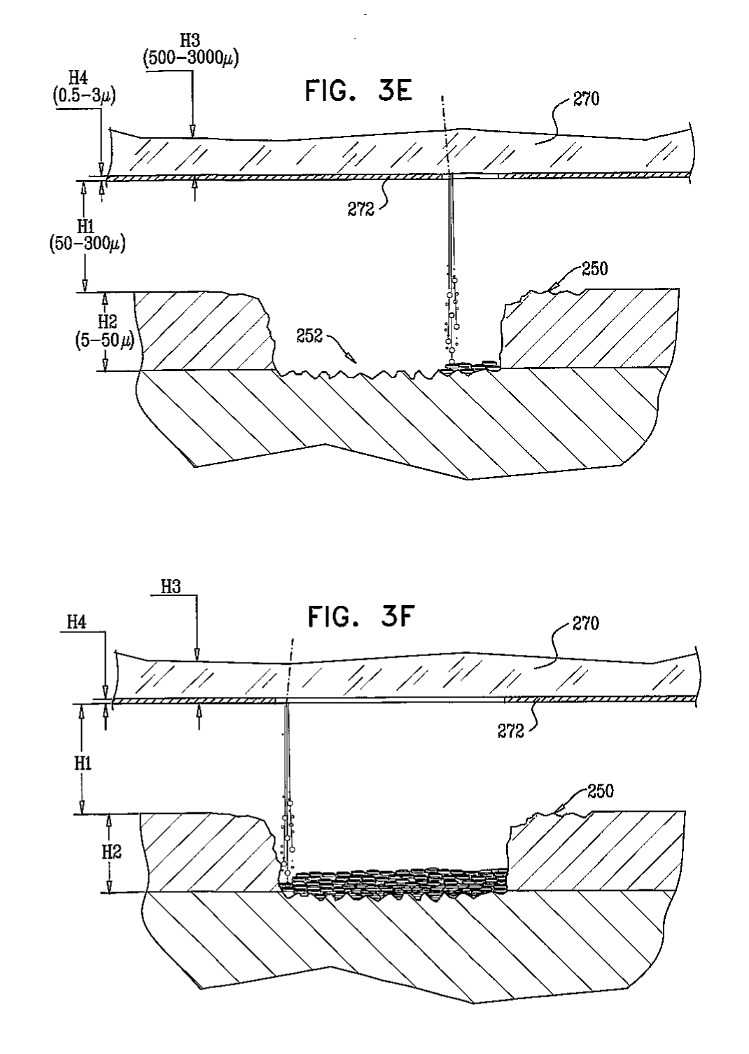

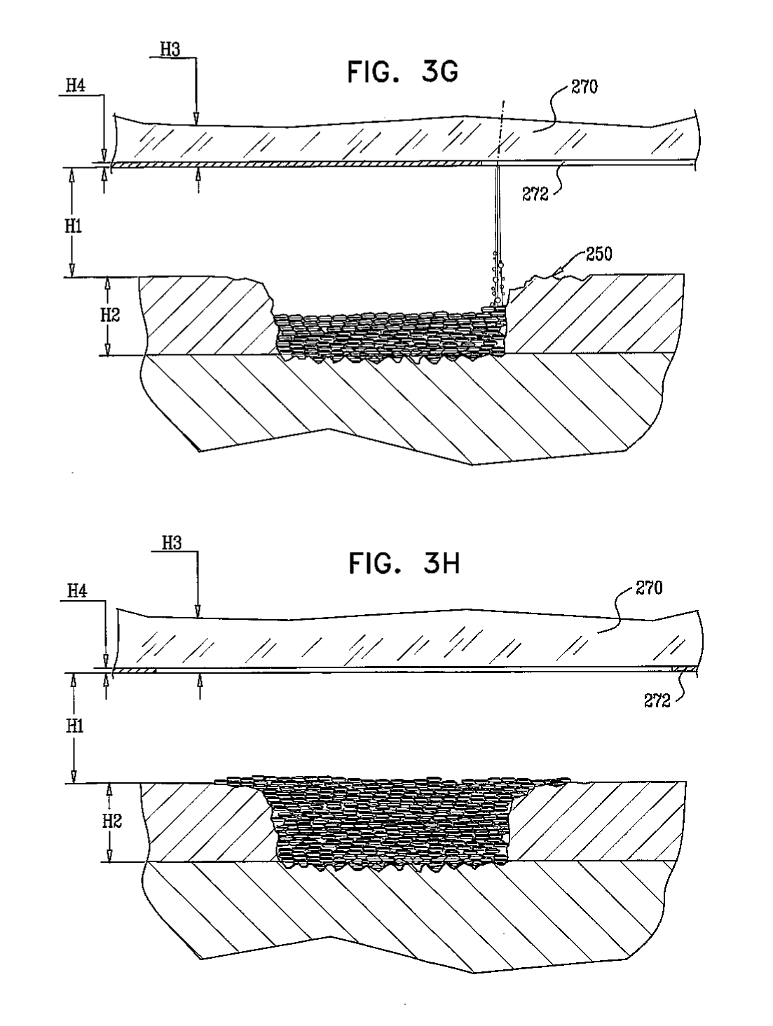

Reference is now made to FIGS. 3A-3H, which are simplified sectional illustrations showing the operation of the system of FIG. 1. FIG. 3A shows a typical missing conductor defect, such as cut 110 (FIG. 1). Initially, as noted above, the control assembly 124 receives an input identifying the type and location of the defect, typically from an automatic optical inspection system.

In the stage shown in FIG. 3A, the control assembly 124 causes the optical head assembly 116 to be displaced so that objective lens module 164 overlies the defect and is focused on the defect. An image of the defect is acquired, preferably at two wavelength bands, preferably centered at approximately 600 nm and 500 nm, and a fluorescence image, centered at approximately 400 nm, is also preferably acquired.

The image is analyzed by control assembly 124 and is preferably compared to a reference, such as CAM data, thereby to confirm the existence and type of defect and to provide a detailed contour of the defect, preferably including definition of at least one conductor repair area 250 and at least one substrate repair area 252.

Turning now to FIGS. 3B, 3C and 3D, it is seen that laser pretreatment of conductor repair area 250 and substrate repair area 252 is carried out. It is a particular feature of the present invention that the objective lens module 164 need not be displaced from its orientation relative to the defect at this stage since the laser and the inspection subassembly share the same focus.

It is appreciated that the pre-treatment of conductor repair area 250 and of substrate repair area 252 are typically different. The general purpose of the pretreatment of conductor repair area 250 and substrate repair area 252 is to provide enhanced adhesion between a conductor material to be deposited and the existing conductor and substrate by surface roughening thereof, through laser ablation. For example, if a Q-switched microchip 30 milliwatt 532 nm laser producing sub-nanosecond pulses is employed, roughening of the substrate and conductor surfaces is achieved by using a spot size, typically, of 10 micron diameter, to produce an X-Y grid of trenches, typically having a depth of 4-6 microns. It is appreciated that depending on the composition of the substrate and of the conductor, the laser energy impinging on a unit area of the surface is varied, for example, by varying the scan speed of the laser beam on the surface or by adjusting the power of the impinging laser beam.

Reference is now made to FIG. 3E, which illustrates initial laser beam impingement on a donor substrate 270 and resulting deposition of a conductor material 272, forming part of donor substrate 270, onto substrate repair area 252, and to FIGS. 3F and 3G, which illustrate further laser beam impingement on donor substrate 270 and resulting deposition of conductor material 272 onto substrate repair area 252. As seen in FIGS. 3E, 3F and 3G, the donor substrate 270 is preferably located at a distance, designated by reference H1, typically about 50-300 microns, above the surface of the conductor repair area 250 and the laser beam is focused on the donor substrate 270 by suitable displacement of the objective lens module 164.

Donor substrate 270 is typically made of a material transparent to the laser's wavelength, which may be rigid, such as glass, or flexible, such as plastic, which is coated on one side with a thin layer of conductor material 272.

As seen in FIGS. 3E, 3F and 3G, the height of the conductor, designated H2, is typically about 5-50 microns, the thickness of the donor substrate 270, designated by 113, is typically in the range of 500-3000 microns, and the thickness of conductor material 272, designated by 114, is typically in the range of 0.5-3 microns.

Preferably the inspection subassembly is employed before and during deposition to monitor the X-Y position of the donor substrate 270 in order to ensure that conductor material 272 is present at all relevant times in a region covering all expected laser beam impingement locations thereon. This functionality is enabled by the fact that the laser and the inspection subassembly share the same focus.

It is a particular feature of the invention that the same laser which is used for surface roughening is also used for deposition. Here, deposition is achieved, for example, if a Q-switched microchip 30 milliwatt 532 nm laser producing sub-nanosecond pulses is employed, by using a spot of size typically of 10 micron diameter, to fill in conductor repair area 250 and substrate repair area 252.

FIG. 3H illustrates the conductor repair area 250 and substrate repair area 252 following the completion of deposition over the conductor repair area 250 and substrate repair area 252. It is appreciated that, while in the illustrated embodiment shown in FIGS. 3E, 3F, 3G and 3H the deposited material appears as individual deposits, the resulting conductor formed thereby takes on a generally uniform appearance.

Typically, following the completion of the deposition, a subsequent inspection of conductor repair area 250 and substrate repair area 252, similar to inspection described in reference to FIG. 3A, is performed.

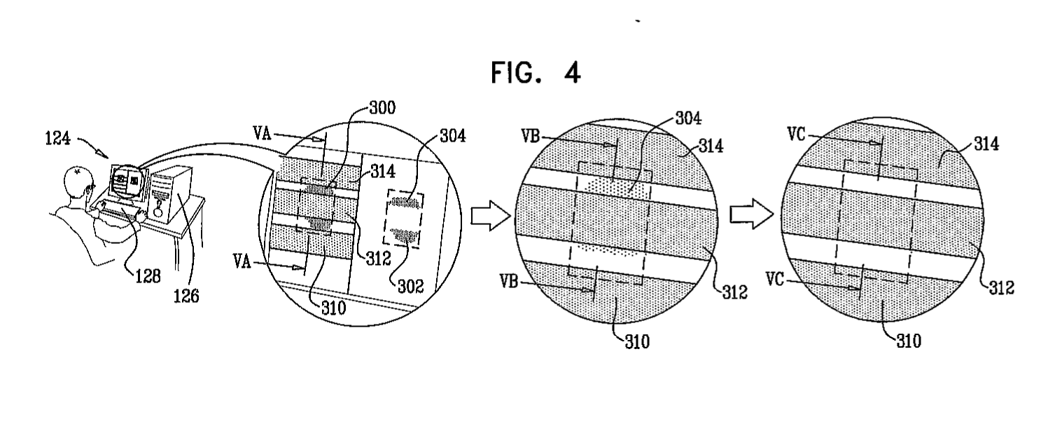

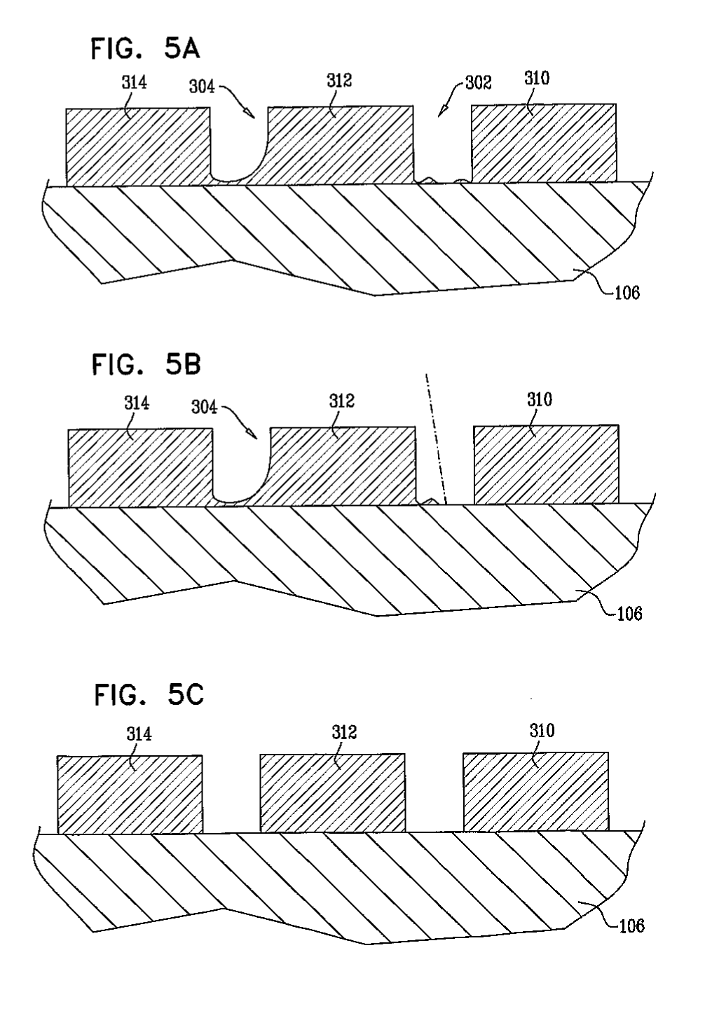

Reference is now made to FIG. 4, which is a simplified illustration of additional functionality of the system for repairing electrical circuits of FIG. 1, and to FIGS. 5A-5C, which are simplified sectional illustrations showing the operation of the functionality of FIG. 4.

As seen in FIG. 4, the system for repairing electrical circuits of FIG. 1, which includes control assembly 124, computer 126 and user interface 128, has identified an excess conductor defect 300 in PCB 106.

In the illustrated example shown in FIG. 4, and as seen particularly in FIG. 5A, the excess conductor defect 300 includes first and second excess conductor material regions 302 and 304. First excess conductor material region 302 lies between conductors 310 and 312 and second excess conductor material region 304 lies between conductors 312 and 314. It is appreciated that excess conductor defect 300 may be formed during the manufacturing of PCB 106 (FIG. 1) or may result from residual conductor material deposited during the process of FIGS. 3E-3H due to sputtering.

In the stage shown in FIG. 5A, the control assembly 124 causes the optical head assembly 116 (FIGS. 1 and 2) to be displaced so that objective lens module 164 (FIG. 2) overlies the defect and is focused on the defect. An image of the defect is acquired, preferably at two wavelength bands, preferably centered at approximately 600 nm and 500 nm, and a fluorescence image, centered at approximately 400 nm, is also preferably acquired.

The image is analyzed by control assembly 124 and is preferably compared to a reference, such as CAM data, thereby to confirm the existence and type of defect and to provide a detailed contour of the defect, preferably including definition of at least one conductor removal area, in the illustrated example, first and second excess conductor material regions 302 and 304.

Turning now to FIGS. 5B and 5C, it is seen that laser ablation of the excess conductor material in first and second excess conductor material regions 302 and 304 is carried out. It is a particular feature of the present invention that the objective lens module 164 need not be displaced from its orientation relative to the defect at this stage since the laser and the inspection subassembly share the same focus.

It is appreciated that the laser ablation of first and second excess conductor material regions 302 and 304 is achieved, typically, if a Q-switched microchip 30 milliwatt 532 nm laser producing sub-nanosecond pulses is employed, by using a spot size, typically, of 5-20 microns diameter. It is appreciated that depending on the composition of the excess conductor material, the laser energy impinging on a unit area of the surface is varied, for example, by varying the scan speed of the laser beam on the surface or by adjusting the power of the impinging laser beam.

Preferably the inspection subassembly is employed before and during laser ablation to monitor the X-Y position of PCB 106 in order to ensure that the laser beam impinges on first and second excess conductor material regions 302 and 304 while not impinging on conductors 310, 312 and 314. This functionality is enabled by the fact that the laser and the inspection subassembly share the same focus.

It is a particular feature of the invention that the same laser which is used for surface roughening and deposition, as described with reference to FIGS. 1-3H, is also used for laser ablation.

Typically, following the completion of the laser ablation, a subsequent inspection of PCB 106, similar to inspection described in reference to FIG. 5A, is performed.

It is appreciated that the laser ablation functionality described hereinabove with reference to FIGS. 4 and 5A-5C for performing laser ablation of excess conductor material regions 302 and 304 may also be used on the same PCB 106 together with the surface roughening and deposition functionalities described hereinabove with reference to FIGS. 3A-3H, if multiple defects are found on PCB 106 or to remove excess conductor material deposited during the deposition process.

It is also appreciated that both the surface roughening and deposition functionalities, described hereinabove with reference to FIGS. 3A-3H, and the laser ablation functionality, described hereinabove with reference to FIGS. 4 and 5A-5C, may be each be employed, as needed, one or more times, in any suitable order, in either multiple locations or the same location on PCB 106.

It will be appreciated by persons skilled in the art that the present invention is not limited by what has been particularly shown and described hereinabove. Rather the present invention includes both combinations and subcombinations of various features described herein and improvements and variations which would occur to persons skilled in the art upon reading the foregoing description and which are not in the prior art.

1. A method of repairing electrical circuits comprising:
employing a laser and at least one laser beam delivery pathway for laser pre-treatment of at least one conductor repair area of a conductor formed on a circuit substrate; and
employing said laser and at least part of said at least one laser beam delivery pathway for application of at least one laser beam to a donor substrate in a manner which causes at least one portion of said donor substrate to be detached therefrom and to be transferred to at least one predetermined conductor location.

2. A method of repairing electrical circuits according to claim 1 and wherein said pre-treatment comprises laser ablation.

3. A method of repairing electrical circuits according to claim 1 and wherein said laser is operated at different power levels during said laser pre-treatment and said application to said donor substrate.

4. A method of repairing electrical circuits according to claim 1 and wherein said pre-treatment comprises pre-treatment of a substrate repair area and pre-treatment of a conductor repair area.

5. A method of repairing electrical circuits according to claim 4 and wherein said laser ablation produces surface roughening of said substrate repair area and said conductor repair area.

6. A method of repairing electrical circuits according to claim 5 and wherein said pre-treatment of said substrate repair area and said pre-treatment of said conductor repair area include different extents of surface roughening.

7. A method of repairing electrical circuits according to claim 1 and wherein said at least one conductor repair area is selected by automated optical inspection.

8. A method of repairing electrical circuits according to claim 1 and also comprising employing said laser and said at least one laser beam delivery pathway for laser ablation of excess conductor material.

9. A method of repairing electrical circuits according to claim 8 and wherein said excess conductor material is formed by material detached from said donor substrate.

10. A method of repairing electrical circuits according to claim 8 and wherein said laser ablation of excess conductor material is performed subsequent to said application of at least one laser beam to a donor substrate, which is in turn performed subsequent to said laser pre-treatment.

11. A method of repairing electrical circuits comprising:
employing a laser and at least one laser beam delivery pathway for laser ablation of excess conductor material in at least one conductor repair area of a conductor formed on a circuit substrate; and
employing said laser and at least part of said at least one laser beam delivery pathway for application of at least one laser beam to a donor substrate in a manner which causes at least one portion of said donor substrate to be detached therefrom and to be transferred to at least one predetermined conductor location.

12. A method of repairing electrical circuits according to claim 11 and wherein said laser ablation of excess conductor material effects repair of short circuits.

13. A method of repairing electrical circuits according to claim 11 and wherein said laser is operated at different power levels during said laser ablation and said application to said donor substrate.

14. A method of repairing electrical circuits according to claim 11 and also comprising surface roughening of said at least one conductor repair area.

15. A method of repairing electrical circuits according to claim 11 and wherein said at least one conductor repair area is selected by automated optical inspection.

16. A method of repairing electrical circuits comprising:
pre-treatment of at least one circuit substrate repair area of a circuit substrate and of at least one conductor repair area of a conductor formed on said circuit substrate and lying adjacent said at least one circuit substrate repair area; and
applying at least one laser beam to a donor substrate in a manner which causes at least one portion of said donor substrate to be detached therefrom and to be transferred to at least one predetermined circuit substrate location in said at least one circuit substrate repair area and to at least one predetermined conductor location in said at least one conductor repair area, thereby to at least partially overlap a portion of said conductor at said at least one conductor repair area and to form at least an extension of said conductor in said at least one circuit substrate repair area.

17. A method of repairing electrical circuits according to claim 16 and wherein said pre-treatment comprises laser ablation.

18. A method of repairing electrical circuits according to claim 16 and wherein said pre-treatment and said applying are carried out by the same laser.

19. A method of repairing electrical circuits according to claim 18 and wherein said pre-treatment and said applying are carried out by the same laser at different power levels.

20. A method of repairing electrical circuits according to claim 18 and wherein said pre-treatment of said substrate repair area and of said conductor repair area are carried out by the same laser at different power levels.

21. A method of repairing electrical circuits according to claim 20 and wherein said pre-treatment of said substrate repair area and of said conductor repair area include different extents of surface roughening.

22. A method of repairing electrical circuits according to claim 17 and wherein said laser ablation produces surface roughening.

23. A method of repairing electrical circuits according to claim 16 and wherein said at least one predetermined substrate location in said at least one substrate repair area and said at least one predetermined conductor location in said at least one conductor repair area are selected by automated optical inspection.

24. A system for repairing electrical circuits comprising:
a laser and a laser beam delivery pathway;
laser pre-treatment functionality utilizing said laser and at least part of said laser beam delivery pathway for laser pre-treatment of at least one conductor repair area of a conductor formed on a circuit substrate; and
conductor deposition functionality utilizing said laser and at least part of said laser beam delivery pathway for application of at least one laser beam to a donor substrate in a manner which causes at least one portion of said donor substrate to be detached therefrom and to be transferred to at least one predetermined conductor location.

25. A system for repairing electrical circuits comprising:
a laser and a laser beam delivery pathway;
excess conductor ablation functionality employing said laser and at least part of said laser beam delivery pathway for laser ablation of excess conductor material in at least one conductor repair area of a conductor formed on a circuit substrate; and
conductor deposition functionality employing said laser and at least part of said laser beam delivery pathway for application of at least one laser beam to a donor substrate in a manner which causes at least one portion of said donor substrate to be detached therefrom and to be transferred to at least one predetermined conductor location.

26. A system for repairing electrical circuits according to claim 25 and wherein said laser ablation of excess conductor material effects repair of short circuits.

27. A system for repairing electrical circuits comprising:
a laser and a laser beam delivery pathway;
pre-treatment functionality employing said laser and at least part of said laser beam delivery pathway for treatment of at least one circuit substrate repair area of a circuit substrate and of at least one conductor repair area of a conductor formed on said circuit substrate and lying adjacent said at least one circuit substrate repair area; and
conductor deposition functionality employing said laser and at least part of said laser beam delivery pathway for application of at least one laser beam to a donor substrate in a manner which causes at least one portion of said donor substrate to be detached therefrom and to be transferred to at least one predetermined circuit substrate location in said at least one circuit substrate repair area and to at least one predetermined conductor location in said at least one conductor repair area, thereby to at least partially overlap a portion of said conductor at said at least one conductor repair area and to form at least an extension of said conductor in said at least one circuit substrate repair area.
